(19) United States
(12) Patent Application Publication
(10) Pub. No.: US 2013/0105209 A1
(43) Pub. Date: May 2, 2013

(54) INORGANIC FILLER AND ELECTRIC MATERIAL CONTAINING THE SAME

(71) Applicant: Elite Electronic Material (Kunshan) CO., LTD., Jiangsu Province (CN)

(72) Inventor: RONG-TAO WANG, Jiangsu Province (CN)

(73) Assignee: ELITE ELECTRONIC MATERIAL (KUNSHAN) CO., LTD., Jiangsu Province (CN)

(21) Appl. No.: 13/666,450

(22) Filed: Nov. 1, 2012

(30) Foreign Application Priority Data
Nov. 2, 2011 (CN) 201110340878.6

(51) Int. Cl. C08K 3/22; C08K 5/06; C08K 5/03; C08K 5/3417; C08K 5/523; H05K 1/03; C08K 5/50; C08K 5/3492; C08K 5/5399; C08K 5/53; B32B 27/12; B32B 27/20; C08L 63/02; C08K 3/32

(52) U.S. Cl. 174/258; 106/444; 523/427; 523/429; 442/117

(57) ABSTRACT

An inorganic filler containing (1) from 50 to 60 parts by weight of SiO₂; (2) from 5 to 20 parts by weight of Al₂O₃; (3) from 0 to 10 parts by weight of CaO; (4) from 15 to 30 parts by weight of B₂O₃; (5) from 0 to 5 parts by weight of MgO; (6) from 0 to 1 parts by weight of Na₂O, K₂O or a combination of both; and (7) from 0 to 5 parts by weight of TiO₂; based on a total weight of the filler, and having a maximum particle diameter below 100 μm is introduced. A resin composition containing the inorganic filler and application in printed circuit boards are also introduced. A laminate prepared by the inorganic filler provides a good drilling function, a good dielectric performance and a good high frequency transmission function in high frequency transmission printed circuit board.

### CROSS-REFERENCE TO RELATED APPLICATION

This non-provisional application claims priority under 35 U.S.C. §119(a) on Patent Application No(s). 201110340878.6 filed in China on Nov. 2, 2011, the entire contents of which are hereby incorporated by reference.

### FIELD OF THE INVENTION

The present invention relates to an electric material, in particular to an inorganic filler applicable in printed circuit boards, a resin composition containing the inorganic filler, and their application for manufacturing printed circuit boards.

### BACKGROUND OF THE INVENTION

A laminate is a raw material for manufacturing printed circuit boards. In general, conventional manufacturing laminate method, a resin composition is impregnated into a glass fiber fabric and then baked to form a prepreg, and the prepreg is laminated with upper and lower copper foils and then pressed to form a copper clad laminate by vacuum and hot press processes, wherein the prepreg is cured to form an insulating layer of the copper clad laminate.

To improve the heat conduction, laser drilling property and thermal expansion coefficient of the copper clad laminate insulating layer, generally, an amount of the inorganic filler is added to the resin composition.

Dielectric constant (Dk) and dissipation factor (Df) are commonly used for describing the dielectric performance of a substance in the industry. The smaller the values of Dk and Df, the better is the dielectric performance The conventional inorganic filler includes silicon dioxide (in a molten state, a non-molten state, or with a porous structure), aluminum hydroxide, aluminum oxide, magnesium oxide, talc, mica powder or an eutectic mixture of oxides, such as silicon dioxide and aluminum oxide. Since the complex inorganic filler of the eutectic mixture of silicon dioxide and aluminum oxide comes with a good drilling property like the E-glass filler and G2-C powder (by SIBELCO), therefore the complex inorganic filler is extensively used for manufacturing laminates. However, the conventional complex inorganic fillers usually come with a poor dielectric performance In the frequency of 1 MHz, the dielectric constant (Dk) generally falls within a range of 5.0˜6.0, and the dissipation factor (Df) generally falls within a range of 0.001˜0.002, or even higher, so that the conventional complex inorganic fillers cannot meet the industrial requirement of high frequency transmissions.

### SUMMARY OF THE INVENTION

It is a primary objective of the present invention to overcome the aforementioned drawback of the prior art by providing an inorganic filler used for manufacturing a laminate of a printed circuit board. Compared with the conventional inorganic fillers including the E-glass filler and the G2-C powder, the inorganic filler of the present invention has a better drilling property and a better dielectric performance, and the laminate manufactured with the inorganic filler is used for manufacturing a high frequency transmission printed circuit board to provide a good high frequency transmission function.

To achieve the aforementioned and other objectives, the present invention provides an inorganic filler comprising: (1) from 50 to 60 parts by weight of SiO2; (2) from 5 to 20 parts by weight of Al₂O₃; (3) from 0 to 10 parts by weight of CaO; (4) from 15 to 30 parts by weight of B₂O₃; (5) from 0 to 5 parts by weight of MgO; (6) from 0 to 1 parts by weight of Na₂O, K₂O or a combination of both; and (7) from 0 to 5 parts by weight of TiO₂; based on a total weight of the filler; and the inorganic filler has a maximum particle diameter below 100 μm.

Preferably, the inorganic filler of the present invention comprises: (1) from 52 to 58 parts by weight of SiO2; (2) from 8 to 15 parts by weight of Al₂O₃; (3) from 2 to 5 parts by weight of CaO; (4) from 15 to 22 parts by weight of B₂O₃; (5) from 2 to 3 parts by weight of MgO; (6) from 0 to 0.1 parts by weight of Na₂O, K₂O or a combination of both; and (7) from 0 to 0.1 parts by weight of TiO₂; based on a total weight of the filler; and the inorganic filler has a maximum particle diameter preferably controlled within a range of 1˜10 μm.

Compared with the conventional inorganic fillers, such as the E-glass filler, G2-C powder and so on, because of including special oxides and oxide content, the inorganic filler of the present invention has smaller Dk/Df values so as to provide a better dielectric performance.

An important factor resides on that the CaO content of the inorganic filler of the present invention is controlled within a range of 0˜10wt %, which is lower than the CaO content of other conventional inorganic fillers, and the dielectric performance tests show that the inorganic filler of the present invention with smaller Dk/Df values due to the lower CaO content, so as to provide a better dielectric performance.

In addition, the inorganic filler of the present invention has a higher B₂O₃ content, than that of the conventional inorganic filler, and the dielectric performance tests show that the higher B₂O₃ content of the inorganic filler of the present invention results in the smaller Dk/Df values, so as to provide a better dielectric performance.

The data listed in Table 1 show that the inorganic filler of the present invention has smaller Dk/Df values than the conventional inorganic filler, such as the E-glass filler, G2-C powder and so on, so as to provide a better dielectric performance.

TABLE 1
Comparison of the dielectric performance of the conventional inorganic
fillers and the inorganic filler of the present invention

| | | | Inorganic filler of the |
|---|---|---|---|
| Composition | E-glass filler | G2-C filler | present invention |
| SiO₂ | 52~56 | 50~62 | 50~60 |
| Al₂O₃ | 12~16 | 11~19 | 5~20 |
| CaO | 16~26 | 6~27 | 0~10 |
| B₂O₃ | 5~10 | 4~13 | 15~30 |
| MgO | 0~5 | 0~6 | 0~5 |
| Na₂O & K₂O | 0~1 | 0~1 | 0~1 |
| TiO₂ | 0 | 0 | 0~5 |
| Dk(1 MHz) | 6.6 | 5 | 4.4 |
| Dk(10 GHz) | 6.6 | — | 4.7 |
| Df(1 MHz) | 0.0012 | 0.002 | 0.0006 |
| Df(10 GHz) | 0.0066 | — | 0.0035 |

In the manufacturing method of the inorganic filler of the present invention, the mineral or additive prepared according to a specific proportion of oxides is placed into a high-temperature furnace, and then calcinated, picked, crushed, graded and manufactured to produce the inorganic filler with a particle diameter of nano scale or micro scale depending on actual requirements. In general, the particle diameter falls below 100 μm, preferably in a range of 1˜10 μm. The smaller particle diameter can improve the dispersion of the inorganic filler in resin composition and the flow glues of filling into holes in a later process of manufacturing the printed circuit board.

Preferably, the inorganic filler of the present invention has a dielectric constant less than 4.5 at 1MHz and a dissipation factor less than 0.001 at 1 MHz. Preferably, the dielectric constant of the inorganic filler is generally 4.4 at 1 MHz, and the dissipation factor is approximately equal 0.0006 at 1 MHz. According to the inorganic fillers with the aforementioned proportion and the dielectric performance controlled within the preferred ranges, a laminated manufactured with the inorganic filler can be used for manufacturing high frequency transmission printed circuit boards to provide a good high frequency transmission function.

Preferably, the inorganic filler of the present invention further comprises a coupling agent for performing a surface pretreatment of the inorganic filler, wherein the coupling agent is a silane coupling agent, a siloxane coupling agent, a titanate coupling agent, a borate ester coupling agent, a rare earth coupling agent, a zirconate coupling agent, an aluminate coupling agent or a fluorine-containing coupling agent or any combination of the above. With the coupling agent used for performing a surface pretreatment of the inorganic filler, the bonding strength of the inorganic filler and the epoxy resin can be enhanced.

Furthermore, the present invention provides a resin composition containing the inorganic filler as disclosed above and at least one resin. Since the laminate manufactured with the resin composition of the present invention has a good drilling manufacture performance and an excellent dielectric performance, which is applicable for manufacturing high frequency printed circuit boards.

Wherein, the inorganic filler comprises: (1) from 50 to 60 parts by weight of SiO2; (2) from 5 to 20 parts by weight of Al₂O₃; (3) from 0 to 10 parts by weight of CaO; (4) from 15 to 30 parts by weight of B₂O₃; (5) from 0 to 5 parts by weight of MgO; (6) from 0 to 1 parts by weight of Na₂O, K₂O or a combination of both; and (7) from 0 to 5 parts by weight of TiO₂; based on a total weight of the filler; and the inorganic filler has a maximum particle diameter below 100 μm.

The resin is one selected from the collection of an epoxy resin, a phenol resin, a phenolic resin, an anhydride resin, a styrene resin, a butadiene resin, a polyamide resin, a polyimide resin, a polyester resin, a polyether resin, a polyphenylene ether resin, a cyanate resin, an isocyanate resin, a maleimide resin, a benzoxazine resin, a bromide resin, a phosphorus-containing resin, a nitrogen-containing resin or any combination of the above.

Preferably, the resin composition further comprises a curing accelerator including at least one Lewis base such as 2-methylimidazole, 1-methylimidazole, 2-ethyl-4-methylimidazole, 2-phenylimidazole, 2-undecyl-1H-imidazole, 2-phenyl-methylimidazole, boron trifluoride amine complex, ethyl-triphenylphosphonium chloride, 4-dimethylaminopyridine or a Lewis acid of at least one metal salt compound including manganese, iron, cobalt, nickel, copper and zinc or an organic peroxide including dicumyl peroxide.

Preferably, the resin composition further comprises at least one of the following flame retardants: polybrominated diphenylether, 1,1′-(ethane-1,2-diyl)bis[pentabromobenzene], N,N-ethylene-bis(tetrabromophthalimide), bisphenol diphenyl phosphate, ammonium polyphosphate, quinol bis(diphenyl phosphate), bisphenol A bis(diphenyl phosphate), tris(2-hydroxyethyl) phosphine, tris(isopropyl chloride) phosphate, trimethyl phosphate, dimethyl-methyl phosphate, resorcinol bis(xylyl) phosphate, melamine polyphosphate, phosphazene compound, phosphazo compound, 9,10-dihydro-9-oxa-10-phosphaphenanthrene-10-oxide and a derivative thereof or a resin, melamine cyanurate acid and tris(hydroxyethyl isocyanurate).

Preferably, the resin composition further comprises a coupling agent including a silane coupling agent, a siloxane coupling agent, a titanate coupling agent, a borate ester coupling agent, a rare earth coupling agent, a zirconate coupling agent, an aluminate coupling agent, a fluorine-containing coupling agent, or any combination of the above.

In addition, the present invention also provides a prepreg, a laminate and a printed circuit board manufactured by the aforementioned resin composition of the present invention.

Wherein, the prepreg was obtained by impregnating the resin composition according to claim 3 into a reinforced material, and then drying the impregnated substrate to B-stage, and the reinforced material is an inorganic fiber, an organic synthetic fiber or a mixture of thereof. The laminate includes at least one metal foil and at least one insulating layer, and the insulating layer is formed by curing the aforementioned prepreg. The printed circuit board includes at least one type of the aforementioned laminates.

Specifically, the prepreg, the laminate and the printed circuit board are manufactured by the method comprising the following steps:

1. Add the inorganic filler, flame retardant, curing agent, curing accelerator, coupling agent, solvent into the resin varnish, and uniformly stir the solution within a temperature range of 25˜45 to produce a glue.

2. Dip the reinforced material which is generally a glass fiber fabric into the aforementioned glue, and bake in an oven within a range of 120˜260 to produce a prepreg.

3. Superimpose the aforementioned prepreg with the metal foil and press at a pressure within 50˜600 psi and a hot dish temperature range of 50˜260 to form a laminate.

4. The aforementioned laminate is exposed, pre-treated, AOI inspected, blackened, bored, electroplated, etched, and laminated to produce a printed circuit board.

Compared with the conventional inorganic filler, the inorganic filler of the present invention used for manufacturing a printed circuit board provides a good drilling property and an excellent dielectric performance, which is applicable for manufacturing high frequency transmission printed circuit boards.

Next, the present invention will be described in more detail in accordance with examples, but the scope of the invention should not be limited to these examples. All the modification and changes according to the characteristic and spirit of the present invention are involved in the protected scope of the invention.

### DETAILED DESCRIPTION OF THE PREFERRED EMBODIMENTS

The objects, characteristics and effects of the present invention will become apparent with the detailed description of the preferred embodiments and the illustration of related drawings as follows.

### Example 1

### Preparation (I) of Inorganic Filler

The raw material was prepared according to the following proportion of oxides

(1) 56wt % of SiO₂; (2) 12wt % of Al₂O₃; (3) 5wt % of CaO; (4) 20wt % of B₂O₃; (5) 0.002wt % of MgO; (6) 0.001wt % of Na₂O and 0.001wt % of K₂O; (7) 0.001wt % of TiO₂.

The oxides were mixed in aforementioned proportion and added into a high-temperature furnace and calcinated at 1500 for 48 hours, and then the product is picked, crushed, and graded. In the preparation process, the inorganic filler has a particle diameter controlled below 100 μm. In this embodiment of the present invention, the inorganic filler has a particle diameter controlled within a range of 1˜10 μm, so that the electronic material containing the inorganic filler can have a good performance.

### Example 2

### Preparation (II) of Inorganic Filler

The raw material was prepared according to the following proportion of oxides:

(1) 52wt % of SiO₂; (2) 15wt % of Al₂O₃; (3) 0.1wt % of CaO; (4) 28wt % of B₂O₃; (5) 0.002wt % of MgO; (6) 0.001wt % of Na₂O and 0.001 wt % of K₂O; and (7) 0.001 wt % of TiO₂.

The preparation method and a particle diameter of the filler were the same as Example 1.

### Embodiment 3

### Preparation (I) of Resin Composition

The raw material of the resin composition was prepared according to the following proportion:

(1) 50 wt % of bisphenol A phenolic epoxy resin; (2) 50 wt % of methyl phenolic epoxy resin; (3) 5 wt % of N,N-diethyl cyanoacetamide; (4) 0.5 wt % of 2-methylimidazole; (5) 50 wt % of butanone; (6) 40 wt % of the inorganic filler obtained in Example 1; and (7) 0.2 wt % of a silane coupling agent.

The aforementioned composites were blended uniformly at a temperature range of 25˜45 to get a glue.

### Example 4

### Preparation (II) of Resin Composition

The raw material of the resin composition was prepared according to the following proportion:

(1) 50 wt % of bisphenol A phenolic epoxy resin; (2) 50 wt % of methyl phenolic epoxy resin; (3) 5 wt % of N,N-diethyl cyanoacetamide; (4) 0.5 wt % of 2-methylimidazole; (5) 50 wt % of butanone; (6) 40 wt % of the inorganic filler obtained in Example 2; and (7) 0.2 wt % of a silane coupling agent.

The aforementioned composites were blended uniformly at a temperature range of 25˜45 to produce a glue.

### Example 5

### Preparation (I) of Prepreg

The resin composition prepared in Example 3 was uniformly soaked into a glass fiber fabric and baked at 170 in an oven for 3 minutes to get a prepreg.

### Example 6

### Preparation (II) of Prepreg

The resin composition prepared in Example 4 was impregnated into a glass fiber fabric and baked at 170 in an oven for 3 minutes to get a prepreg.

### Example 7

### Preparation (I) of Laminate

Two copper foils were laminated on both sides of the prepreg prepared in Example 5 respectively, and then placed in a vacuum hot press. Within a pressure range of 50˜600psi and a hot dish temperature range of 50˜260, the two copper foils and the prepreg were pressed to produce a copper clad laminate, wherein the prepreg was cured to form an insulating layer between the two copper foils. In other examples, more than one prepreg could be stacked with one another between the two copper foils to assure that the prepregs could be cured to form an effective insulating layer.

### Example 8

### Preparation (II) of Laminate

Two copper foils were laminated on both sides of the prepreg prepared in Example 6 respectively, and then placed into a vacuum hot press. Within a pressure range of 50˜600psi and a hot dish temperature range of 50˜260, the two copper foils and the prepreg were pressed to produce a copper clad laminate, wherein the prepreg was cured to form an insulating layer between the two copper foils. In other examples, more than one prepreg could be stacked with one another between the two copper foils to assure that the prepregs could be cured to form an effective insulating layer.

### Comparative Example 1

The raw material of the inorganic filler was prepared according to the following proportion:

(1) 56wt % of SiO₂; (2) 12w t% of Al₂O₃; (3) 20wt % of CaO; (4) 5wt % of B₂O₃; (5) 0.01wt % of MgO; and (6) 0.001wt % of Na₂O and 0.001wt % of K₂O.

The inorganic filler was obtained in the same manner as in Example 1.

### Comparative Example 2

The raw material of the resin composition is prepared according to the following proportion:

(1) 50 wt % of bisphenol A phenolic epoxy resin; (2) 50 wt % of methyl phenolic epoxy resin; (3) 5 wt % of N,N-diethyl cyanoacetamide; (4) 0.5 wt % of 2-methylimidazole; (5) 50 wt % of butanone; (6) 40 wt % of the inorganic filler obtained in Comparative Example 1; and (7) 0.2 wt % of a silane coupling agent.

The aforementioned composites were blended uniformly to get a glue.

### Comparative Example 3

The resin compostion prepared in Comparative Example 2 was provided for being uniformly impregnated into a glass fiber fabric, and then baked at 170 in an oven for 3 minutes to get a prepreg.

### Comparative Example 4

The laminate was obtained in substantially the same manner as in Example 7 except that the prepreg prepared in Example 5 was changed into the one gotten in Comparative Example 3.

The laminates obtained from Example 7, Example 8 and Comparative Example 4 were tested according to IPC-TM650, and the testing results are listed in Table 2.

TABLE 2
Comparison of the performance of the laminates

| | Example | Example | Comparative |
|---|---|---|---|
| Property | 7 | 8 | Example 4 |
| Peeling Strength | 9.68 | 9.67 | 9.61 |
| (1 oz) (lb/in) | | | |
| Tg(DSC) ( ) | 153 | 153 | 153 |
| T288(TMA) (min) | >5 | >5 | >5 |
| Z-axis expansion | 2.45 | 2.42 | 2.58 |
| rate (TMA) (%) | | | |
| Moisture | 0.12 | 0.12 | 0.12 |
| absorption (%) | | | |
| Dk(1 MHz) | 4.2 | 4.0 | 4.6 |
| Df(1 MHz) | 0.0068 | 0.0065 | 0.0080 |
| Drill wear after | 26.5 | 26.2 | 27.2 |
| drilling 2500 | | | |
| holes (μm) | | | |
| 288 Solder | >300 | >300 | >300 |
| dipping (s) | | | |
| Pressure | Pass | Pass | Pass |
| cooker test* | | | |

| | |
|---|---|
| Remarks | “Pass” refers to the laminate having no separate |
| | layers or white dot on the surface after the |
| | laminate was processed by high pressure steaming |
| | for 1 hour and dip soldering at 288 for 20 seconds. |

As to the Dk and Df data listed in Table 2, the Dk and Df values of the laminates of Examples 7 and 8 are less than the Dk and Df values of the laminate of Comparative Example 4, so that the laminates of Examples 7 and 8 have a better electric property, showing that the inorganic filler of the present invention provides a better dielectric performance. Compared with the results of the electric properties of the laminates of Examples 7 and 8, the laminate of Example 8 has smaller Dk and Df values, showing that Example 8 has a better dielectric performance because of containing less CaO and more B₂O₃.

Based on the theory of the drill wear measurement, after a drill drills 2500 holes, the cutting edge of the drill keeps on contacting the laminates to have the wear, and a wear occurs at a cutting rounding of a cutting edge, and the wear at the cutting rounding is measured. As to the drill wear data listed in Table 2, the wear of the drill used for drilling 2500 holes for the laminates of Examples 7 and 8 is slightly smaller than that of Comparative Example 4. And the laminates of Examples 7 and 8 show a good drilling manufacture because of using the inorganic filler in present invention.

In summation of the description above, the inorganic filler of the present invention can reduce the dielectric constant and the dissipation factor of the laminate effectively while providing a good drilling manufacture, and thus the inorganic filler of the invention is applicable for manufacturing high frequency transmission printed circuit boards.

### Example 9

### Manufacture of a Printed Circuit Board of the Present Invention

The copper clad laminates manufactured in Example 8 were processed by a microlithography etching process to form a surface circuit, and the prepregs manufactured in Example 6 were stacked alternately between two adjacent copper foils and then processed by a high-temperature and high-pressure pressing process to form a circuit substrate, and the printed circuit board was gotten by a usual process of manufacturing a circuit board. According to the data listed in Table 2, we can predict that the printed circuit board manufactured by the aforementioned method that adopts the inorganic filler of the present invention is applicable for manufacturing a high frequency transmission printed circuit board.

While the invention has been described by means of specific embodiments, numerous modifications and variations could be made thereto by those skilled in the art without departing from the scope and spirit of the invention set forth in the claims.

What is claimed is:

1. An inorganic filler, comprising: (1) from 50 to 60 parts by weight of SiO₂; (2) from 5 to 20 parts by weight of Al₂O₃; (3) from 0 to 10 parts by weight of CaO; (4) from 15 to 30 parts by weight of B₂O₃; (5) from 0 to 5 parts by weight of MgO; (6) from 0 to 1 parts by weight of Na₂O, K₂O or a combination of both; and (7) from 0 to 5 parts by weight of TiO₂; based on a total weight of the filler; and the inorganic filler having a maximum particle diameter below 100 μm.

2. The inorganic filler according to claim 1, wherein the filler have a dielectric constant smaller than 4.5 at 1 MHz and a dissipation factor smaller than 0.001 at 1 MHz.

3. A resin composition, comprising the inorganic filler according to claim 1 and at least one resin.

4. The resin composition according to claim 3, wherein the resin is one selected from the collection of epoxy resin, phenol resin, phenolic resin, anhydride resin, styrene resin, butadiene resin, polyamide resin, polyimide resin, polyester resin, polyether resin, polyphenylene ether resin, cyanate resin, isocyanate resin, maleimide resin, benzoxazine resin, bromide resin, phosphorus-containing resin, and nitrogen-containing resin or any combination thereof.

5. The resin composition according to claim 3, wherein further comprising a curing accelerator including at least one Lewis base selected from the collection of 2-methylimidazole, 1-methylimidazole, 2-ethyl-4-methylimidazole, 2-phenylimidazole, 2-undecyl-1H-imidazole, 2-phenyl-methylimidazole, boron trifluoride amine complex, ethyl-triphenylphosphonium chloride, and 4-dimethylaminopyridine, or at least one Lewis acid of a metal salt compound of manganese, iron, cobalt, nickel, copper or zinc, or an organic peroxide which is dicumyl peroxide.

6. The resin composition according to claim 3, wherein the resin composition further comprises at least one flame retardant selected from the collection of polybrominated diphenylether, 1,1′-(ethane-1,2-diyl)bis[pentabromobenzene], N,N-ethylene-bis(tetrabromophthalimide), bisphenol diphenyl phosphate, ammonium Polyphosphate, quinol bis(diphenyl phosphate), bisphenol A bis(diphenyl phosphate), tris(2-hydroxyethyl) phosphine, tris(isopropyl chloride) phosphate, trimethyl phosphate, dimethyl-methyl phosphate, resorcinol bis(xylyl) phosphate, melamine polyphosphate, phosphazene compound, phosphazo compound, 9,10-dihydro-9-oxa-10-phosphaphenanthrene-10-oxide and a derivative thereof or resin, melamine cyanurate acid and tris(hydroxyethyl isocyanurate).

7. The resin composition according to claim 3, further comprising a coupling agent selected from the collection of a silane coupling agent, a siloxane coupling agent, a titanate coupling agent, a borate ester coupling agent, a rare earth coupling agent, a zirconate coupling agent, an aluminate coupling agent, and a fluorine-containing coupling agent or any combination thereof.

8. A prepreg, obtaining by impregnating the resin composition according to claim 3 into a reinforced material, and then drying the impregnated substrate to B-stage, and the reinforced material is an inorganic fiber, an organic synthetic fiber or a mixture of thereof.

9. A laminate, comprising at least one metal foil and at least one insulating layer, wherein that the insulating layer is formed by curing the prepreg according to claim 8.

10. A printed circuit board, comprising at least one laminate according to claim 9.
